(19) United States
(12) Patent Application Publication
(10) Pub. No.: US 2025/0261318 A1
(43) Pub. Date: Aug. 14, 2025

(54) NETWORKING APPARATUS

(71) Applicant: Verizon Patent and Licensing Inc., Basking Ridge, NJ (US)

(72) Inventors: Charles M. Balboa, Long Valley, NJ (US); Andrew N. Toth, Telford, PA (US); Robert Stewart, Point Pleasant, NJ (US); Jonathan Simmons, Croton-on-Hudson, NY (US); Eric Call, New York, NY (US); Kyle Laidlaw, Ridgewood, NY (US); Joseph Toro, Patchogue, NY (US); Richard Migliaccio, Mount Sinai, NY (US)

(21) Appl. No.: 18/437,729

(22) Filed: Feb. 9, 2024

(51) Int. Cl. H05K 5/00; H04L 43/0811; H05K 5/02

(52) U.S. Cl. CPC H05K 5/0017; H04L 43/0811; H05K 5/0213

(57) ABSTRACT

In an example, a networking apparatus is provided. The networking apparatus includes a set of networking components, a housing assembly configured to house the set of networking components, a set of light sources, and a light guide disposed between the set of light sources and a first housing panel of the housing assembly. The first housing panel includes a first portion having a first thickness and a second portion adjacent the first portion and having a second thickness less than the first thickness. The light guide is configured to direct light from the set of light sources to an inner side of the second portion of the first housing panel to produce a networking icon on an outer side of the second portion of the first housing panel.

### BACKGROUND

A router is a networking device that communicates data packets between computer networks and/or performs traffic directing functions for networks which may include the Internet. A router may be used by a household, an office, etc. to establish a wireless network, configure a database and/or connect to the Internet.

### BRIEF DESCRIPTION OF THE DRAWINGS

While the techniques presented herein may be embodied in alternative forms, the particular embodiments illustrated in the drawings are only a few examples that are supplemental of the description provided herein. These embodiments are not to be interpreted in a limiting manner, such as limiting the claims appended hereto.

FIG. 1A is an illustration of a first perspective view of a networking apparatus according to some embodiments.

FIG. 1B is an illustration of a bottom view of a networking apparatus according to some embodiments.

FIG. 1C is an illustration of a second perspective view of a networking apparatus according to some embodiments.

FIG. 1D is an illustration of a sliced perspective view of a networking apparatus according to some embodiments.

FIG. 1E is an illustration of a backside view of a networking apparatus according to some embodiments.

FIG. 2A is an illustration of a perspective view of a networking apparatus disassembly system comprising a networking apparatus and a jig according to some embodiments.

FIG. 2B is an illustration of a perspective view of a networking apparatus disassembly system comprising a networking apparatus and a jig according to some embodiments.

FIG. 2C is an illustration of a perspective view of one or more protrusions of a jig interacting with a first coupling feature according to some embodiments.

FIG. 2D is an illustration of a perspective view of a networking apparatus disassembly system comprising a networking apparatus and a jig according to some embodiments.

FIG. 2E is an illustration of a block representation of a side view of a first spacing tool, a first housing panel, an indicator light assembly, a base and/or a jig body relative to each other, according to some embodiments.

FIG. 3 is an illustration of an exploded view of an indicator light assembly relative to a first housing panel according to some embodiments.

FIG. 4A is an illustration of a perspective view of a first housing panel according to some embodiments.

FIG. 4B is an illustration of a sliced perspective view of a first housing panel according to some embodiments.

FIG. 4C is an illustration of a cross-sectional view of a first housing panel according to some embodiments.

FIG. 5A is an illustration of a first state of a signal strength indicator icon according to some embodiments.

FIG. 5B is an illustration of a second state of a signal strength indicator icon according to some embodiments.

FIG. 5C is an illustration of a third state of a signal strength indicator icon according to some embodiments.

FIG. 6A is an illustration of a networking apparatus communicating with a telecommunication service site according to some embodiments.

FIG. 6B is an illustration of a networking apparatus establishing a connection between a client device and a public network according to some embodiments.

### DETAILED DESCRIPTION OF EXAMPLE EMBODIMENTS

Subject matter will now be described more fully hereinafter with reference to the accompanying drawings, which form a part hereof, and which show, by way of illustration, specific example embodiments. This description is not intended as an extensive or detailed discussion of known concepts. Details that are well known may have been omitted, or may be handled in summary fashion.

The following subject matter may be embodied in a variety of different forms, such as structures, apparatuses, methods, devices, components, and/or systems. Accordingly, this subject matter is not intended to be construed as limited to any example embodiments set forth herein. Rather, example embodiments are provided merely to be illustrative.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The following provides a discussion of some types of scenarios in which the disclosed subject matter may be utilized and/or implemented.

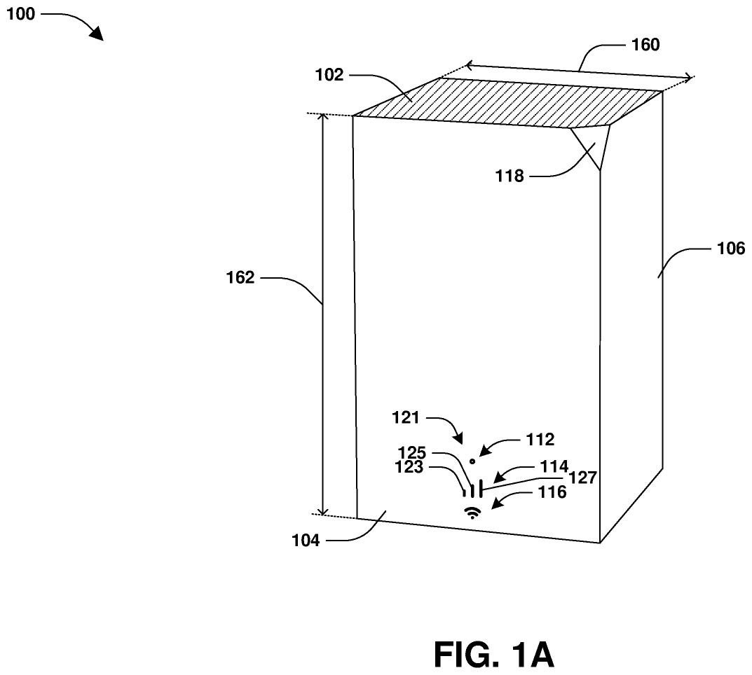

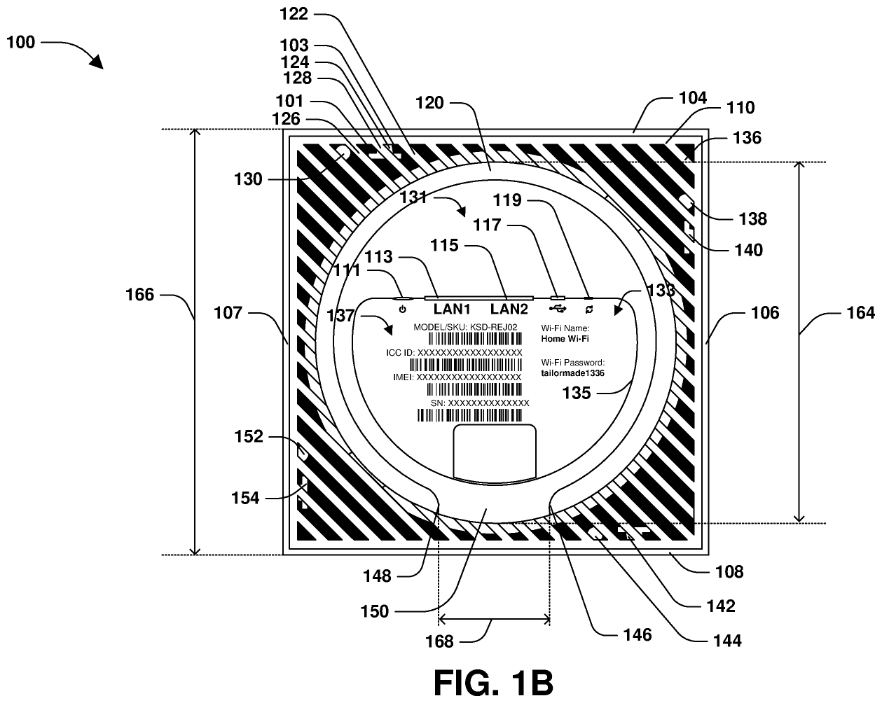

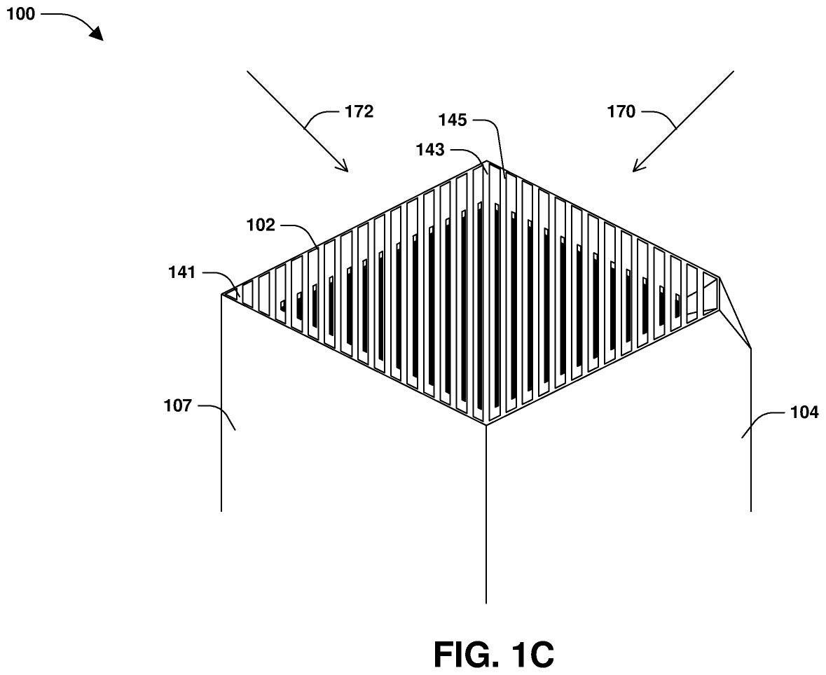

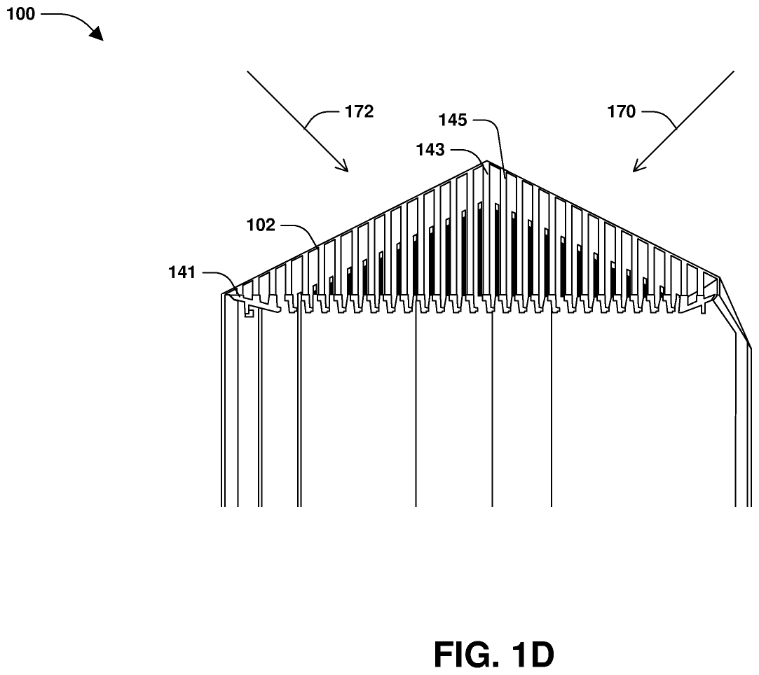

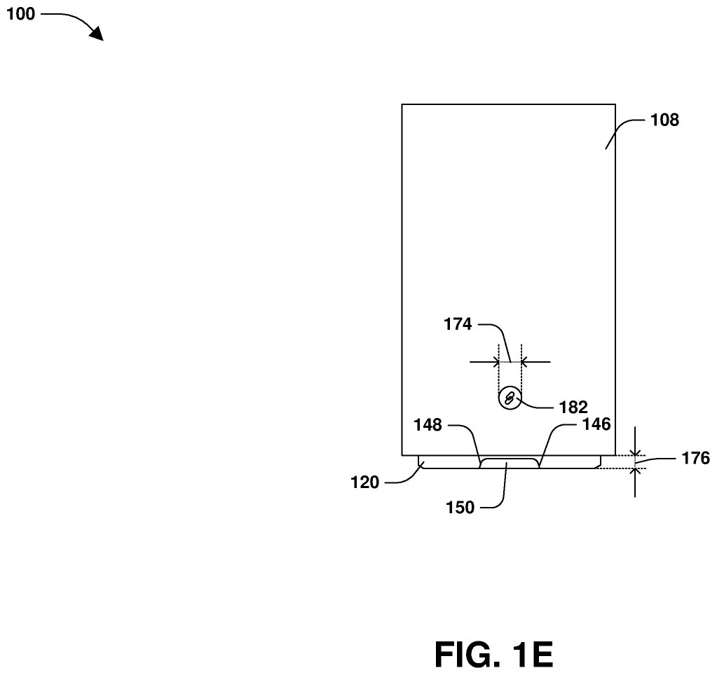

FIGS. 1A-1E illustrate aspects of a networking apparatus 100, according to some embodiments. FIG. 1A illustrates a first perspective view of the networking apparatus 100. FIG. 1B illustrates a bottom view of the networking apparatus 100. FIG. 1C illustrates a second perspective view of the networking apparatus 100. FIG. 1D illustrates a sliced perspective view of the networking apparatus 100. FIG. 1E illustrates a backside view of the networking apparatus 100.

In some embodiments, the first housing panel 104 (e.g., a display panel) of the networking apparatus 100 comprises an icon display region 121 (shown in FIG. 1A) in which one or more icons are displayed. The one or more icons may comprise a system status icon 112, a signal strength indicator icon 114 and/or a wireless network status icon 116. In some examples, a color and/or one or more other characteristics of an icon may be controlled to convey information, such as a status of the networking apparatus 100.

In some examples, the networking apparatus 100 comprises a set of networking components, which may include, for example, an antenna, a carrier configured to hold the antenna, a wireless communication module connected to the antenna, etc. The set of networking components may be configured to perform networking operations to provide one or more telecommunication services (e.g., Internet service) to one or more users. For example, the networking apparatus 100 may establish a wireless network, such as a wireless local area network (WLAN) (e.g., a Wi-Fi network). In some examples, the networking apparatus 100 may connect one or more client devices to one or more networks (by performing wide area network (WAN) routing, for example). The one or more networks may include the Internet, one or more remote networks, one or more remote private networks, etc.

The networking apparatus 100 may comprise a housing assembly comprising a first housing panel 104, a second housing panel 106, a third housing panel 108 (shown in FIG. 1E) opposing the first housing panel 104, a fourth housing panel 107 (shown in FIG. 1C) opposing the second housing panel 106, a fifth housing panel 102 (e.g., a top housing panel) and/or a base 110 (shown in FIG. 1B) (e.g., a bottom housing panel) opposing the fifth housing panel 102. The housing assembly may comprise a tapered corner 118 between the first housing panel 104, the second housing panel 106 and/or the fifth housing panel 102. The housing assembly may be configured to house the set of networking components. For example, the housing assembly may at least partially surround the set of networking components. The set of networking components may be disposed in a housing chamber defined by the housing assembly (e.g., the housing chamber may be defined by inner walls of housing panels of the housing assembly). In some examples, the fifth housing panel 102 may correspond to a top side of the networking apparatus 100, and/or the base 110 may correspond to a bottom side of the networking apparatus 100.

The base 110 may comprise a wall 120 (shown in FIGS. 1B and 1E), which may protrude from the base 110 such that the wall 120 interfaces with a surface (e.g., the surface of a desk, a table, a cabinet, etc.) upon which the networking apparatus 100 is set. The wall 120 may at least partially encircle a region 131, which may include a groove 133 (e.g., a depression in the base 110) defined by a sidewall 135 of the base 110. In some examples, the base 110 may comprise one or more ports, such as a power port 111, a first local area network (LAN) port 113, a second LAN port 115 and/or a Universal Serial Bus (USB) port 117. Other ports (for networking, data transfer, configuration installation, etc., for example) are within the scope of the present disclosure. In some examples, the one or more ports may face the groove 133. The groove 133 may provide space for a connector (e.g., a power connector, a LAN connector, a USB connector, etc.) of a cable to be inserted into and/or coupled with a port of the one or more ports. In some examples, the wall 120 may define a cable space 150 for the cable to be disposed. The cable space 150 may be defined by a first end 146 of the wall 120 and a second end 148 of the wall 120. Alternatively and/or additionally, the base 110 may comprise a reset button 119 adjacent the one or more ports (e.g., the reset button 119 may face the groove 133).

In some examples, information 137 may be displayed by a surface (in the groove 133, for example) of the base 110 (e.g., the information 137 may be printed on the surface and/or a label attached to the surface). The information 137 may comprise at least one of a name (e.g., a service set identifier (SSID)) of the wireless network (e.g., Home Wi-Fi), a password of the wireless network, a model identifier and/or stock keeping unit (SKU) associated with the networking apparatus 100, an International Mobile Equipment Identity (IMEI) associated with the networking apparatus 100, a serial number associated with the networking apparatus 100, a quick-response (QR) code (not shown) (and/or other type of code) for connecting to the wireless network (e.g., the QR code may be used to automatically connect a client device to the wireless network without manually entering the password of the wireless network), and/or other information associated with the networking apparatus 100 and/or the wireless network.

In some examples, the base 110 comprises a first venting structure 136, which may be used to exhaust air (e.g., relatively hotter air) out of the housing chamber and/or introduce air (e.g., relatively cooler air) into the housing chamber. The first venting structure 136 may comprise a first louver 126, a second louver 128, a third louver 122 and/or other louvers. In some examples, openings defined by louvers of the first venting structure 136 (e.g., a first vent opening 101 defined by the first louver 126 and the second louver 128, a second vent opening 103 defined by the second louver 128 and the third louver 122, etc.) may expose and/or may provide for access to one or more mechanisms of the housing assembly, such as one or more first coupling features, one or more first fasteners (e.g., a first fastener 130, a second fastener 138, a third fastener 144 and/or a fourth fastener 152), and/or one or more other mechanisms. In some examples, a fastener (e.g., the first fastener 130, the second fastener 138, the third fastener 144 and/or the fourth fastener 152) of the one or more first fasteners may comprise at least one of a clip, a screw, a bolt, a nut, etc.

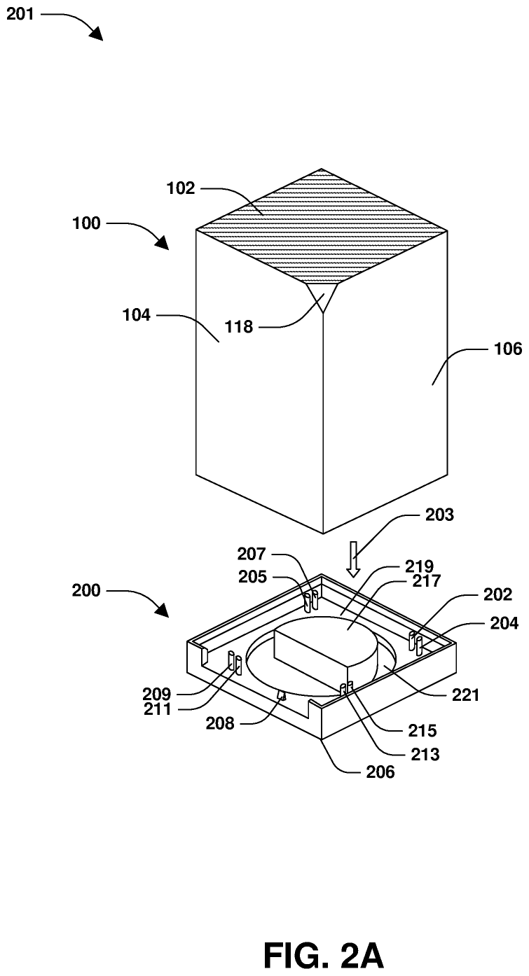

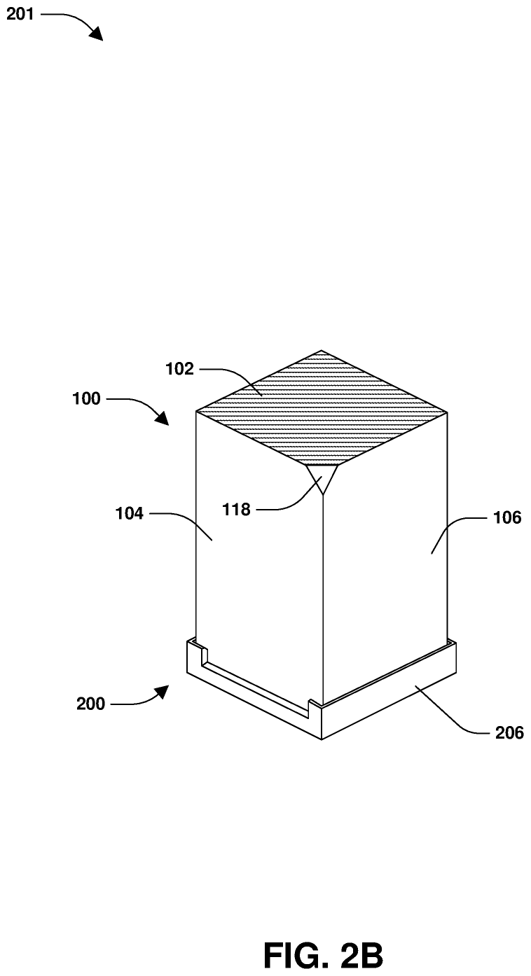

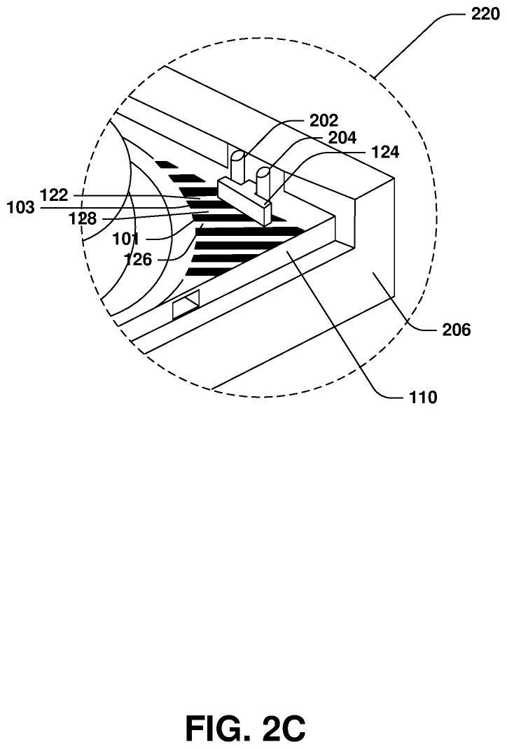

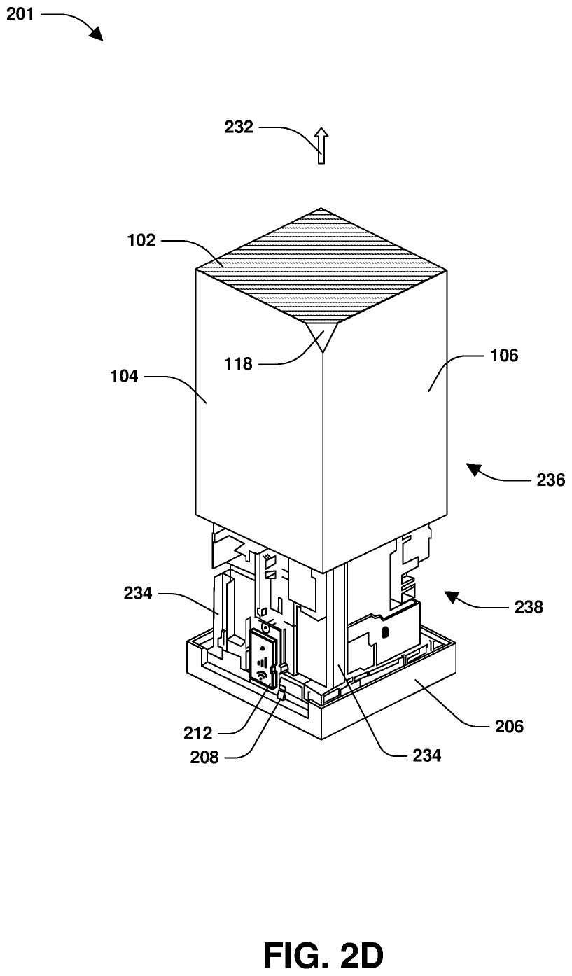

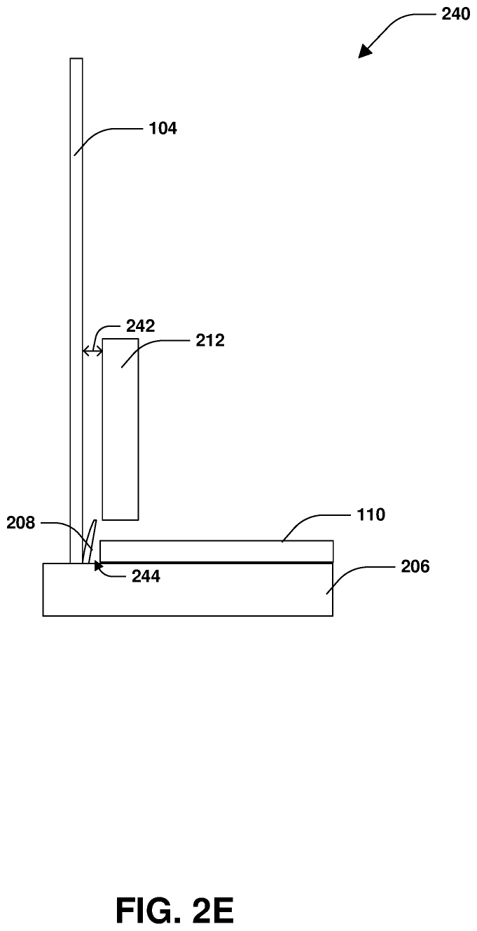

In some examples, a coupling feature (e.g., a first coupling feature 124, a second coupling feature 140, a third coupling feature 142 and/or a fourth coupling feature 154) of the one or more first coupling features may be used to couple the base 110 to a housing body (identified with reference number 236 in FIG. 2D) of the housing assembly. The housing body 236 may comprise the first housing panel 104, the second housing panel 106, the third housing panel 108, the fourth housing panel 107 and/or the fifth housing panel 102. The first housing panel 104, the second housing panel 106, the third housing panel 108, the fourth housing panel 107 and/or the fifth housing panel 102 may comprise two, three, four, five or more separate structures (e.g., five individual panels) that are attached, such as with mechanical fasteners, adhesives, etc. In some examples, the first housing panel 104, the second housing panel 106, the third housing panel 108, the fourth housing panel 107 and/or the fifth housing panel 102 (e.g., a portion of the housing body 236 and/or the housing body 236 as a whole) may be integrally formed, one piece formed, a single composite piece, etc. Alternatively and/or additionally, the first housing panel 104, the second housing panel 106, the third housing panel 108, the fourth housing panel 107 and/or the fifth housing panel 102 (e.g., a portion of the housing body 236 and/or the housing body 236 as a whole) may be formed via at least one of 3D printing (e.g., using 3D printable material, such as 3D printable plastic), additive manufacturing, etc.

A bottom view of at least one of the first housing panel 104, the second housing panel 106, the third housing panel 108 and/or the fourth housing panel 107 is shown in FIG. 1B, in accordance with some embodiments. In an example, the first coupling feature 124 may couple the base 110 to the first housing panel 104 (when the first coupling feature 124 is in an engaged state, for example), the second coupling feature 140 may couple the base 110 to the second housing panel 106 (when the second coupling feature 140 is in an engaged state, for example), the third coupling feature 142 may couple the base 110 to the third housing panel 108 (when the third coupling feature 142 is in an engaged state, for example), and/or the fourth coupling feature 154 may couple the base 110 to the fourth housing panel 107 (when the fourth coupling feature 154 is in an engaged state, for example).

Referring to FIG. 1C, in some examples, the fifth housing panel 102 may comprise a second venting structure 141. The second venting structure 141 may overlie at least some of the set of networking components (e.g., the second venting structure 141 may overlie at least one of the antenna, the carrier, etc.). In some examples, the second venting structure 141 may comprise a plurality of louvers. FIG. 1D provides a sliced perspective view of the second venting structure 141 to show cross-sectional shapes of the plurality of louvers. In some embodiments of the present disclosure, such as shown in FIG. 1D, a cross-sectional shape of at least some of the plurality of louvers may be z-shape. For example, one, some and/or all of the plurality of louvers of the second venting structure 141 may be z-shaped louvers. Other cross-sectional shapes of the plurality of louvers of the second venting structure 141 are within the scope of the present disclosure. The plurality of louvers may comprise a fourth louver 143 (e.g., a z-shaped louver), a fifth louver 145 (e.g., a z-shaped louver), etc.

In some examples, the plurality of louvers (i) obstructs visibility into the housing chamber (e.g., inner chamber of the housing assembly) from a first perspective 170 and/or (ii) allows visibility into the housing chamber from a second perspective 172, such as due, at least in part, to the cross-sectional shape (e.g., z-shape) of at least some of the plurality of louvers. For example, a person viewing the networking apparatus 100 from the first perspective 170 may view less of the housing chamber (and/or may not be able to view the housing chamber) than a person viewing the networking apparatus 100 from the second perspective 172. From the perspective of a person that is in front of the networking apparatus 100 and/or facing a front side (e.g., the first housing panel 104) of the networking apparatus 100, the person may view less of the housing chamber (and/or may not be able to view the housing chamber), as compared to the perspective of a person that is behind the networking apparatus 100 and/or facing a back side (e.g., the third housing panel 108) of the networking apparatus 100. Alternatively and/or additionally, in comparison with louvers that are not z-shaped, z-shaped louvers may provide for a more visually uniform appearance (e.g., less and/or zero shadows, less and/or zero negative space, etc.) from the perspective of a person that is in front of the networking apparatus 100 and/or facing the front side (e.g., the first housing panel 104) of the networking apparatus 100 (and/or viewing the networking apparatus 100 from the first perspective 170). Thus, the networking apparatus 100 may have a more visually appealing aesthetic, such as due, at least in part, to the plurality of louvers at least partially hiding inner components (e.g., at least one of the antenna, the carrier, etc.) of the networking apparatus 100 from a person proximate the networking apparatus 100 such that the inner components (and/or vent openings and/or louvers of the second venting structure 141) appear invisible and/or at least partially hidden to the person.

Referring to FIG. 1E, the third housing panel 108 may comprise a button 182 (e.g., a push button). The button 182 may be pressed to activate a feature, such as a first security feature. In some examples, the first security feature may correspond to Wi-Fi Protected Setup (WPS) (e.g., the button 182 may be a WPS button). In some examples, the button 182 may be pressed to initiate a WPS operation to connect a client device to the wireless network.

In some examples, a dimension 162 shown in FIG. 1A (e.g., the dimension 162 may correspond to a height of the first housing panel 104 and/or the housing body 236) is between at least about 160 millimeters to at most about 260 millimeters (and/or between at least about 210 millimeters to at most about 220 millimeters). In some examples, a dimension 160 shown in FIG. 1A (e.g., the dimension 160 may correspond to a width of the first housing panel 104 and/or the housing body 236) is between at least about 80 millimeters to at most about 180 millimeters (and/or between at least about 125 millimeters to at most about 135 millimeters). In some examples, a dimension 166 shown in FIG. 1B (e.g., the dimension 166 may correspond to a width of the second housing panel 106 and/or the fourth housing panel 107 and/or a depth of the housing body 236) is between at least about 80 millimeters to at most about 180 millimeters (and/or between at least about 125 millimeters to at most about 135 millimeters). In some examples, a dimension 164 shown in FIG. 1B (e.g., the dimension 164 may correspond to a diameter of a circle at least partially defined by the wall 120) is between at least about 60 millimeters to at most about 160 millimeters (and/or between at least about 105 millimeters to at most about 115 millimeters). In some examples, a dimension 168 shown in FIG. 1B (e.g., the dimension 168 may correspond to a distance between the first end 146 and the second end 148 of the wall 120) is between at least about 16 millimeters to at most about 36 millimeters (and/or between at least about 22 millimeters to at most about 30 millimeters). In some examples, a dimension 174 shown in FIG. 1E (e.g., the dimension 174 may correspond to a diameter of the button 182) is between at least about 5 millimeters to at most about 25 millimeters (and/or between at least about 10 millimeters to at most about 20 millimeters). In some examples, a dimension 176 shown in FIG. 1E (e.g., the dimension 176 may correspond to a height of the wall 120) is between at least about 1 millimeter to at most about 20 millimeters (and/or between at least about 5 millimeters to at most about 10 millimeters). In some examples, at least some of the housing assembly (e.g., exterior rigid components such as the first housing panel 104, the second housing panel 106, the third housing panel 108, the fourth housing panel 107, the fifth housing panel 102 and/or the base 110) may comprise (e.g., may be at least partially made of) polycarbonate, acrylonitrile butadiene styrene (ABS) plastic (e.g., a PC/ABS blend comprising post-consumer recycled content), and/or other material. In some examples, the wall 120 and/or a rubber foot (e.g., a rubber foot that protrudes from the base 110 and/or interfaces with a surface, such as the surface of a desk, a table, a cabinet, etc.) may comprise thermoplastic polyurethane and/or other material.

FIGS. 2A-2E illustrate aspects of a networking apparatus disassembly system 201, in accordance with some embodiments. FIG. 2A illustrates a perspective view of the networking apparatus disassembly system 201. In some examples, the networking apparatus disassembly system 201 may comprise a jig 200 to disassemble the networking apparatus 100. For example, the networking apparatus 100 may be disassembled using the jig 200 for at least one of repairing the networking apparatus 100, refurbishing the networking apparatus 100, reconfiguring the networking apparatus 100, investigating one or more aspects of the networking apparatus 100, replacing one or more components (e.g., an electronic and/or networking component that functions incorrectly), cleaning one or more components of the networking apparatus 100, etc.

In some examples, the jig 200 may comprise a jig body 206 and one or more first protrusions (e.g., one or more pins) protruding from the jig body 206. In some examples, the one or more first protrusions comprise a first protrusion 202, a second protrusion 204, etc. In some examples, the first protrusion 202 and/or the second protrusion 204 may protrude from the jig body 206 and/or may interact with the first coupling feature 124. For example, the first protrusion 202 and/or the second protrusion 204 may contact (e.g., directly and/or indirectly contact) the first coupling feature 124 when the networking apparatus 100 is set in a first position relative to the jig body 206 (e.g., when the networking apparatus 100 is placed upon the jig body 206).

FIG. 2B illustrates the networking apparatus disassembly system 201 when the networking apparatus 100 has the first position relative to the jig 200, in accordance with some embodiments. In some examples, the first protrusion 202 and/or the second protrusion 204 may be moved in a first direction 203 (shown in FIG. 2A) to transfer the networking apparatus 100 to the first position (e.g., the first protrusion 202 and/or the second protrusion 204 may contact the first coupling feature 124 during placement of the networking apparatus 100 onto the jig 200). For example, the first protrusion 202 and/or the second protrusion 204 may contact the first coupling feature 124 while the networking apparatus 100 is moved in the first direction 203. In some examples, the contact (e.g., direct and/or indirect contact) of the first protrusion 202 and/or the second protrusion 204 with the first coupling feature 124 may disengage the first coupling feature 124 to allow the housing body 236 to be moved relative to the base 110.

FIG. 2C illustrates a representation 220 of a perspective view of the first protrusion 202 and/or the second protrusion 204 of the jig 200 interacting with the first coupling feature 124, in accordance with some embodiments. Structures and/or components other than the jig body 206, the base 110 (comprising louvers of the first venting structure 136), the first protrusion 202 and/or the second protrusion 204 are removed from the representation 220 provided in FIG. 2C in order to show positions of the jig body 206, the base 110 (comprising louvers of the first venting structure 136), the first protrusion 202 and/or the second protrusion 204 relative to each other while the networking apparatus 100 has the first position relative to the jig 200. The first protrusion 202 may extend through the second vent opening 103 defined by the second louver 128 and the third louver 122. The second protrusion 204 may extend through the first vent opening 101 defined by the first louver 126 and the second louver 128. In some examples, the first coupling feature 124 (and/or other coupling features of the networking apparatus 100) may comprise a snap feature that is disengaged (e.g., released) by the first protrusion 202 and/or the second protrusion 204. Other types of coupling mechanisms of the first coupling feature 124 (and/or other coupling features of the networking apparatus 100) are within the scope of the present disclosure.

In some examples, the one or more first protrusions of the jig 200 comprise one or more other protrusions (in addition to the first protrusion 202 and/or the second protrusion 204, for example) to interact with one or more other coupling features (e.g., the second coupling feature 140, the third coupling feature 142 and/or the fourth coupling feature 154) of the networking apparatus 100. For example, when the networking apparatus 100 has the first position relative to the jig 200 (and/or while the networking apparatus 100 is transferred to the first position), (i) a protrusion 205 and/or a protrusion 207 (shown in FIG. 2A) of the jig 200 may contact the second coupling feature 140, which may disengage the second coupling feature 140, (ii) a protrusion 209 and/or a protrusion 211 may contact the third coupling feature 142, which may disengage the third coupling feature 142, and/or (iii) a protrusion 213 and/or a protrusion 215 may contact the fourth coupling feature 154, which may disengage the fourth coupling feature 154. Thus, in accordance with some embodiments, coupling features of the networking apparatus 100 may be disengaged (automatically, for example) when the networking apparatus 100 has the first position (by way of the one or more first protrusions of the jig 200 contacting the coupling features, for example), which may release the base 110 from the housing body 236 such that the housing body 236 can be pulled apart and/or separated from the base 110.

In some examples, a technician and/or a robot tasked with disassembling the networking apparatus 100 may (i) place the networking apparatus 100 in the first position relative to the jig 200 and/or (ii) (once the networking apparatus 100 is in the first position, for example) pull the housing body 236 (which may include the first housing panel 104, the second housing panel 106, the third housing panel 108, the fourth housing panel 107 and/or the fifth housing panel 102) in a second direction 232 (shown in FIG. 2D) to separate the housing body 236 from the base 110. In some examples, prior to (or after) placing the networking apparatus 100 in the first position relative to the jig 200, the one or more first fasteners may be loosened and/or removed (by the technician and/or the robot, for example) using a tool such as at least one of a screwdriver, a drill, etc. The tool may access the one or more first fasteners via vent openings defined by louvers of the first venting structure 136 of the base 110.

In some examples, a fastener (e.g., the first fastener 130, the second fastener 138, the third fastener 144 and/or the fourth fastener 152) of the one or more first fasteners may comprise a captive fastener (e.g., a captive screw), which may provide a secure joining (between the base 110 and the housing body 236, for example) and/or may be configured to remain attached to the networking apparatus 100, even when the captive fastener is loosened, which may provide for safer and/or easier disassembly of the networking apparatus 100 (by way of avoiding loosened screws from escaping during disassembly of the networking apparatus 100, for example). In some examples, when the one or more first fasteners are loosened and/or the one or more first coupling features are disengaged, the housing body 236 may be separated from the base 110 by the technician and/or the robot (i) gripping the housing body 236 and/or (ii) applying, to the housing body 236, a force that moves the housing body 236 in the second direction 232. Thus, in accordance with some embodiments, the networking apparatus disassembly system 201 enables the networking apparatus 100 to be more quickly disassembled with a reduced amount of (and/or zero) tools, screws, etc.

FIG. 2D illustrates the housing body 236 being moved in the second direction 232 to separate the housing body 236 from the base 110, in accordance with some embodiments. According to some embodiments, the housing assembly comprises a chassis 234 configured to support one or more components of the set of networking components. In some examples, the chassis 234 comprises an assembly of at least one of arms, posts, beams, etc. to which at least some of the set of networking components are mounted. In some examples, moving the housing body 236 relative to the base 110 (such as in the second direction 232 shown in FIG. 2D) exposes at least some of the chassis 234 and at least some of the set of networking components. In this way, the technician and/or a robot may gain access to a component of the set of networking components (to at least one of service, test, clean, replace, etc. the component, for example).

According to some embodiments, the jig 200 comprises a first spacing tool 208 (shown in FIGS. 2A, 2D and 2E) protruding from the jig body 206. The first spacing tool 208 may be configured to (i) separate the first housing panel 104 from an indicator light assembly 212 (shown in FIGS. 2D-2E), and/or (ii) mitigate a force from the first housing panel 104 to the indicator light assembly 212 (during the movement of the housing body 236 relative to the base 110, for example), thereby protecting the indicator light assembly 212 from damage during disassembly of the networking apparatus 100.

FIG. 2E illustrates a block representation 240 of a side view of the first spacing tool 208, the first housing panel 104, the indicator light assembly 212, the base 110, and/or the jig body 206 (upon which the networking apparatus 100 is set, for example). Structures and/or components other than the first spacing tool 208, the first housing panel 104, the indicator light assembly 212, the base 110 and/or the jig body 206 are removed from the block representation 240 provided in FIG. 2E in order to show positions of the first spacing tool 208, the first housing panel 104, the indicator light assembly 212, the base 110 and/or the jig body 206 relative to each other while the networking apparatus 100 has the first position relative to the jig 200. The first spacing tool 208 may extend through an opening 244 between an opening 244 between the first housing panel and the base 110. Embodiments are contemplated in which the first spacing tool 208 extends through a vent opening defined by the first venting structure 136 of the base 110. In some examples, the first spacing tool 208 may interface with the first housing panel 104 to separate the first housing panel 104 from the indicator light assembly 212 by a distance 242 (which may be at least about 0.1 millimeters, for example). In some examples, the first spacing tool 208 may apply, to the first housing panel 104, a force in a direction away from the indicator light assembly 212, which may mitigate (e.g., prevent) collision of the first housing panel 104 with the indicator light assembly 212 (thereby protecting the indicator light assembly 212 from being damaged by the first housing panel 104, for example).

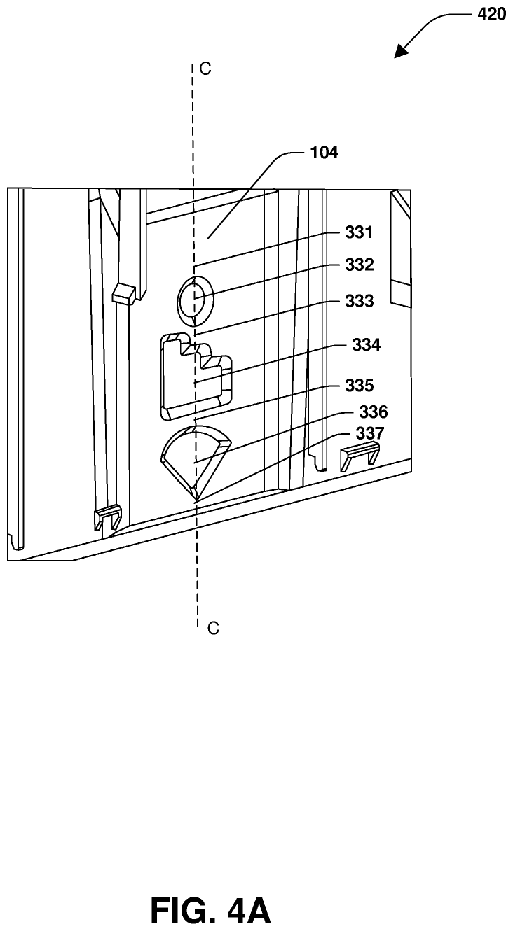

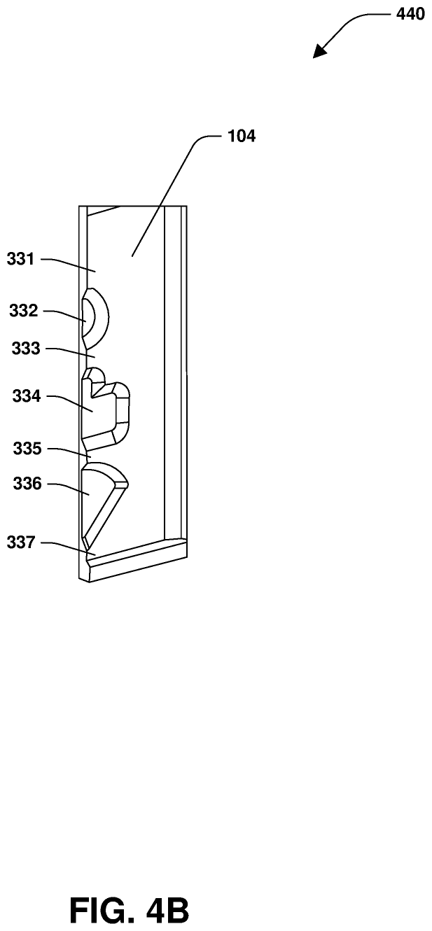

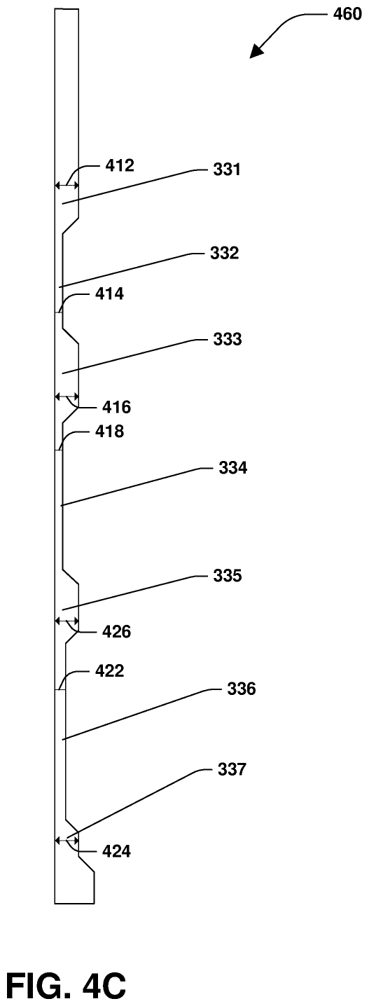

For example, the first spacing tool 208 (e.g., a shim and/or a pry tool) may interface with a detent of the housing body 236 (e.g., a bottom edge of the first housing panel 104 may comprise the detent), which may allow the first spacing tool 208 to pry the first housing panel 104 away from the indicator light assembly 212 (and/or away from the center of the networking apparatus 100). In some examples, during normal operation of the networking apparatus 100, one or more respective portions of the indicator light assembly 212 may be disposed in (and/or pressed into) one or more recesses defined by the first housing panel 104 (e.g., the one or more recesses may be defined by a first locally thinned portion 332, a second locally thinned portion 334 and/or a third locally thinned portion 336 of the first housing panel 104). Alternatively and/or additionally, the one or more respective portions of the indicator light assembly 212 may be in contact with the first locally thinned portion 332, the second locally thinned portion 334, and/or the third locally thinned portion 336 during normal operation of the networking apparatus 100. In some examples, one or more relatively thicker portions of the first housing panel 104 (e.g., portions 333, 335 and 337 shown in FIG. 4A) may interfere with the indicator light assembly 212 if the housing body 236 were pulled in the second direction 232 (to separate the housing body 236 from the base 110, for example) without using the jig 200. The first spacing tool 208 may deflect the first housing panel 104 a sufficient amount that the one or more relatively thicker portions the first housing panel 104 clear the indicator light assembly 212 while the housing body 236 is pulled off the base 110, which may mitigate damage to the indicator light assembly 212 and/or one or more other portions of the networking apparatus 100.

The jig body 206 may comprise a structure 217 (shown in FIG. 2A). In some examples, the structure 217 may be within (e.g., may at least partially fill) the groove 133 of the base 110 when the networking apparatus 100 is in the first position relative to the jig 200. In some examples, a first surface 219 and/or a second surface 221 of the jig body 206 are in contact (e.g., direct and/or indirect contact) with the base 110 of the networking apparatus 100 when the networking apparatus 100 is in the first position relative to the jig 200.

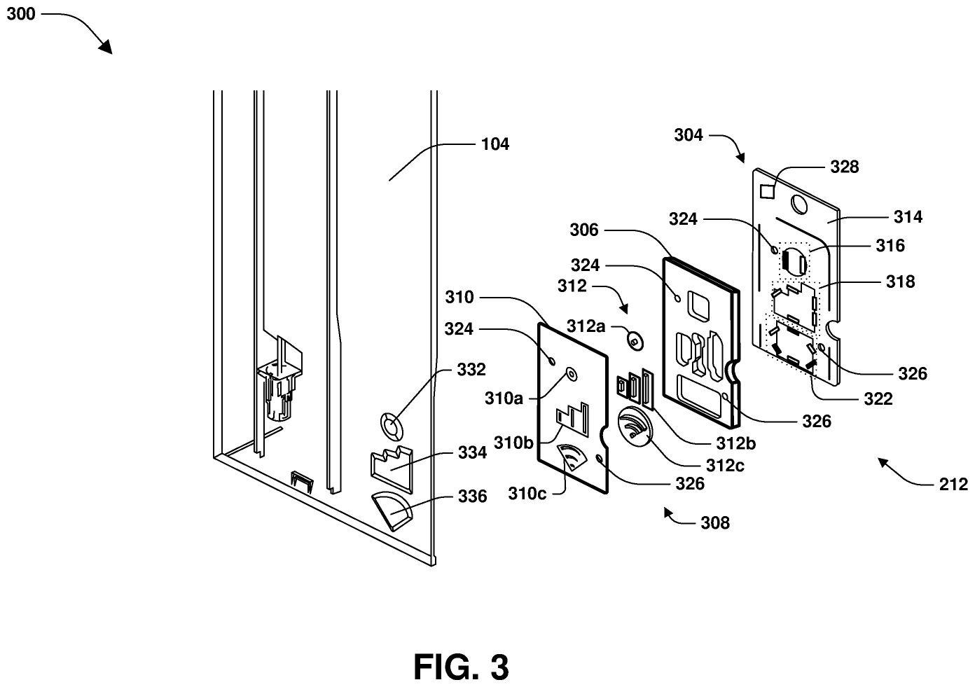

FIG. 3 illustrates a representation 300 of an exploded view of the indicator light assembly 212 relative to the first housing panel 104, in accordance with some embodiments. In some examples, the indicator light assembly 212 comprises a light source module 304, an isolation structure 306 and/or a light guide 308 (e.g., glow-through light guide). In some examples, components of the indicator light assembly 212 (e.g., the light source module 304, the isolation structure 306 and/or the light guide 308) may be attached to each other using one or more fasteners (not shown), such as a fastener through openings 324 of the respective components and/or a fastener through openings 326 of the respective components).

In some examples, the light source module 304 may comprise light sources mounted to a printed circuit board (PCB) 314. In some examples, the networking apparatus 100 comprises a controller 328 mounted to the PCB 314. The controller 328 may be connected to and/or may control at least some of the light sources. In some examples, one, some and/or all of the light sources are each a light-emitting diode (LED). Other types of light sources of the light source module 304 are within the scope of the present disclosure. In some examples, at least some of the light sources are RGB (Red, Green, Blue) LEDs, at least some of the light sources are non-RGB LEDs (which may also be referred to as “white LEDs”) and/or at least some of the light sources are (a single package comprising) White and RGB LEDs (which may also be referred to as “WRGB LEDs”). In FIG. 3, RGB LEDs are shown with black-filled rectangles and non-RGB LEDs are shown as white-filled rectangles, in accordance with some embodiments.

In some examples, the light source module 304 may comprise a first set of (one or more) light sources 316 associated with the system status icon 112, a second set of (one or more) light sources 318 associated with the signal strength indicator icon 114 and/or a third set of (one or more) light sources 322 associated with the wireless network status icon 116.

The isolation structure 306 may separate the light source module 304 from the light guide 308. The isolation structure 306 may comprise (e.g., may be at least partially made of) foam (e.g., isolation foam), which may provide a buffer between the light source module 304 and the light guide 308 and/or may provide tolerance for disassembly and/or assembly of the networking apparatus 100. The isolation structure 306 may comprise (e.g., may be at least partially made of) a light absorbing material.

The light guide 308 may comprise a double injection light guide (and/or may be produced via double injection molding). In some examples, the light guide 308 may comprise a first light guide component 312 and/or a second light guide component 310. In some examples, a double injection molding process may comprise injecting two materials (e.g., two different materials comprising a first material of the first light guide component 312 and/or a second material of the second light guide component 310). In some examples, a first shot (e.g., an initial shot) of the double injection molding process is performed to form the second light guide component 310 (which may comprise a plastic, such as a rigid plastic, for example). A second shot (e.g., after the first shot) of the double injection modeling process may be performed to form the first light guide component 312 (which may comprise a relatively soft and/or flexible material, for example). The first light guide component 312 may comprise (e.g., may be at least partially made of) a translucent material, such as a translucent polycarbonate resin (e.g., Covestro Makrolon® 2407) that may have engineered light diffusion properties. In some examples, using the translucent polycarbonate resin (e.g., Covestro Makrolon 2407) for the first light guide component 312 may provide for improved uniformity of a resulting icon in the icon display region 121 without (unnecessarily) blurring an edge of the resulting icon. In some examples, the second light guide component 310 may be co-molded with the first light guide component 312. The second light guide component 310 may comprise (e.g., may be at least partially made of) a light absorbing material act and thus as a light mask to mitigate bleeding from one icon of the icon display region 121 into a neighboring icon and/or into other (internal) regions of the networking apparatus 100, thereby providing for improved user experience, improved light uniformity of icons in the icon display region 121 and/or improved brightness of the icons in the icon display region 121. Other materials of the light guide 308 are within the scope of the present disclosure. Embodiments are contemplated in which (i) the networking apparatus 100 does not comprise the first light guide component 312 and/or (ii) the networking apparatus 100 leverages an open-air light chamber defined by the second light guide component 310 (e.g., light mask) to produce one or more icons of the icon display region 121.

In some examples, the first light guide component 312 may comprise a first portion 312a associated with the system status icon 112, a second portion 312b associated with the signal strength indicator icon 114 and/or a third portion 312c associated with the wireless network status icon 116. The second light guide component 310 may comprise a first portion 310a associated with the system status icon 112, a second portion 310b associated with the signal strength indicator icon 114 and/or a third portion 310c associated with the wireless network status icon 116.

In some examples, light emitted by one or more light sources of the light source module 304 may be directed by the light guide 308 to the first housing panel 104 to produce a networking icon (in the icon display region 121, for example). In some examples, the light may be directed to an inner surface of a locally thinned portion of the first housing panel 104 to produce the networking icon on an outer surface of the locally thinned portion. In some examples, the locally thinned portion may correspond to a portion, of the first housing panel 104, that has a thickness that is less than a thickness of a portion (of the first housing panel 104) adjacent the portion. In some examples, a thickness of the locally thinned portion of the first housing panel 104 is less than a threshold thickness to allow the light directed to the inner surface of the locally thinned portion to be visible at the outer surface of the locally thinned portion. In some examples, one or more portions of the first housing panel 104 (outside the locally thinned portion, for example) may have a thickness greater than the threshold thickness, which may provide for increased strength of the first housing panel 104 and/or improved protection of the networking apparatus 100.

For example, first light emitted by the first set of light sources 316 may be conducted by the light guide 308 to a first locally thinned portion 332 of the first housing panel 104 to produce the system status icon 112, which may comprise a circle and/or a dot (and/or other symbol). For example, the first light may be conducted through the first portion 312a of the first light guide component 312 and/or the first portion 310a of the second light guide component 310 to an inner surface of the first locally thinned portion 332 of the first housing panel 104 to produce the system status icon 112 on an outer surface of the first locally thinned portion 332 (which may be in the icon display region 121 shown in FIG. 1A, for example). In some examples, a boundary (which may be defined by a change in thickness of the first housing panel 104) of the first locally thinned portion 332 may have a shape corresponding to an outline (e.g., circle) associated with the system status icon 112.

Alternatively and/or additionally, second light emitted by the second set of light sources 318 may be conducted by the light guide 308 to a second locally thinned portion 334 of the first housing panel 104 to produce the signal strength indicator icon 114 (shown in FIG. 1A), which may comprise a first bar 123, a second bar 125 and/or a third bar 127. For example, the second light may be conducted through the second portion 312b of the first light guide component 312 and/or the second portion 310b of the second light guide component 310 to an inner surface of the second locally thinned portion 334 of the first housing panel 104 to produce the signal strength indicator icon 114 on an outer surface of the second locally thinned portion 334 (which may be in the icon display region 121 shown in FIG. 1A, for example). In some examples, a boundary (which may be defined by a change in thickness of the first housing panel 104) of the second locally thinned portion 334 may have a shape corresponding to an outline (e.g., signal strength symbol outline) associated with the signal strength indicator icon 114.

Alternatively and/or additionally, third light emitted by the third set of light sources 322 may be conducted by the light guide 308 to a third locally thinned portion 336 of the first housing panel 104 to produce the wireless network status icon 116 (shown in FIG. 1A), which may comprise a Wi-Fi symbol and/or other symbol. For example, the third light may be conducted through the second portion 312b of the first light guide component 312 and/or the second portion 310b of the second light guide component 310 to an inner surface of the third locally thinned portion 336 of the first housing panel 104 to produce the wireless network status icon 116 on an outer surface of the third locally thinned portion 336 (which may be in the icon display region 121 shown in FIG. 1A, for example). In some examples, a boundary (which may be defined by a change in thickness of the first housing panel 104) of the third locally thinned portion 336 may have a shape corresponding to an outline (e.g., a Wi-Fi symbol outline) associated with the wireless network status icon 116.

FIGS. 4A-4C illustrate aspects of the first housing panel 104, in accordance with some embodiments. FIG. 4A illustrates a representation 420 of a perspective view of the first housing panel 104, in accordance with some embodiments. FIG. 4B illustrates a representation 440 of a sliced perspective view of the first housing panel 104, in accordance with some embodiments. FIG. 4C illustrates a representation 460 of a cross-sectional view of the first housing panel 104, taken along line C-C of FIG. 4A, in accordance with some embodiments. In some examples, the inner surface of the first housing panel 104 is apparent in FIGS. 4A and 4B.

In some examples, the first housing panel may comprise portions 331, 333, 335 and 337 (shown in FIGS. 4A-4C). In some examples, the first locally thinned portion 332 may be adjacent (and/or between) portions 331 and 333. In some examples, the second locally thinned portion 334 may be adjacent (and/or between) portions 333 and 335. In some examples, the third locally thinned portion 336 may be adjacent (and/or between) portions 335 and 337.

In some examples, a first thickness 414 (shown in FIG. 4C) of the first locally thinned portion 332, a second thickness 418 of the second locally thinned portion 334 and/or a third thickness 422 of the third locally thinned portion 336 may be less than (i) a thickness 412 of the portion 331, (ii) a thickness 416 of the portion 333, (iii) a thickness 426 of the portion 335, and/or (iv) a thickness 424 of the portion 337. In some examples, the first thickness 414, the second thickness 418 and/or the third thickness 422 may be less than the threshold thickness. In some examples, thicknesses 412, 416, 426 and/or 424 of portions 331, 333, 335 and/or 337, respectively, may be greater than (and/or equal to and/or less than) than the threshold thickness.

In some examples, the system status icon 112 is configured to convey information, such as a system status, associated with the networking apparatus 100. For example, the system status icon 112 may be configured to convey a sign of life indication (e.g., an indication that the networking apparatus 100 is powered on). In some examples, the controller 328 controls a color and/or illumination level of the system status icon 112 to convey information. For example, the controller 328 may control the color of the system status icon 112 by controlling colors and/or illumination levels of the first set of light sources 316 (e.g., a RGB LED and a non-RGB LED). Light emitted by different light sources of the first set of light sources 316 may be blended together to achieve a desired color of the system status icon 112. In some examples, the system status icon 112 may be controlled to have a first color during a firmware update (e.g., a person viewing the networking apparatus 100 may interpret, based upon the system status icon 112 having the first color, that the networking apparatus 100 is undergoing the firmware update) and/or may be controlled to have a second color while the networking apparatus 100 is performing a security function (e.g., a person viewing the networking apparatus 100 may interpret, based upon the system status icon 112 having the second color, that the networking apparatus 100 is performing the security function). The first color and/or the second color may be selected from a set of colors that the first set of light sources 316 are configured to emit (e.g., blue, green, orange, red, white and/or one or more other colors). Alternatively and/or additionally, the system status icon 112 may be controlled to be illuminated according to a first pattern (e.g., the system status icon 112 may blink a defined number of times) to indicate that the networking apparatus 100 is performing a booting up process.

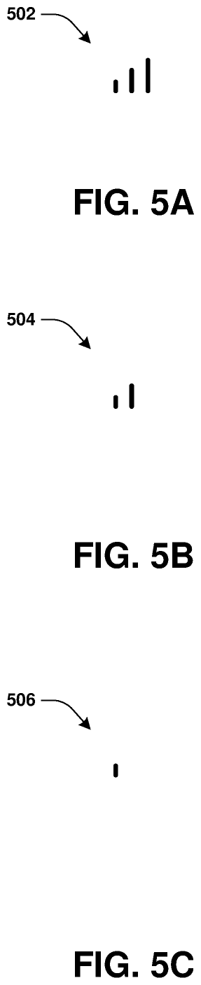

In some examples, the signal strength indicator icon 114 is configured to convey signal strength information associated with the networking apparatus 100. In some examples, the networking apparatus 100 (and/or the controller 328) may monitor a signal strength of a telecommunication service provided by a telecommunication service site. In some examples, the controller 328 controls activation, deactivation and/or illumination level of the first bar 123, the second bar 125 and/or the third bar 127 to convey the signal strength information. FIGS. 5A-5C illustrate various states of the signal strength indicator icon 114, in accordance with some embodiments. FIG. 5A illustrates the signal strength indicator icon 114 in a first state in which (i) the first bar 123 is activated, (ii) the second bar 125 is activated and/or (iii) the third bar 127 is activated. The signal strength indicator icon 114 being in the first state may indicate that the signal strength is within a first range of signal strengths. FIG. 5B illustrates the signal strength indicator icon 114 in a second state in which (i) the first bar 123 is activated, (ii) the second bar 125 is activated and/or (iii) the third bar 127 is deactivated. The signal strength indicator icon 114 being in the second state may indicate that the signal strength is within a second range of signal strengths. In some examples, a maximum value of the second range of signal strengths may be less than a minimum value of the first range of signals strengths. FIG. 5C illustrates the signal strength indicator icon 114 in a third state in which (i) the first bar 123 is activated, (ii) the second bar 125 is deactivated and/or (iii) the third bar 127 is deactivated. The signal strength indicator icon 114 being in the third state may indicate that the signal strength is within a third range of signal strengths. In some examples, a maximum value of the third range of signal strengths may be less than a minimum value of the second range of signals strengths. Alternatively and/or additionally, an illumination level of a bar (e.g., the first bar 123, the second bar 125 and/or the third bar 127) may be controlled to convey information. For example, an illumination level of a bar (e.g., the first bar 123, the second bar 125 and/or the third bar 127) may be reduced (e.g., from about 80% brightness to about 10% brightness) to indicate a reduction of the signal strength.

In some examples, the wireless network status icon 116 is configured to convey wireless network information associated with the networking apparatus 100, such as a status associated with the wireless network established using the networking apparatus 100. In some examples, the controller 328 controls a color and/or illumination level of the wireless network status icon 116 to convey the wireless network information. In some examples, the controller 328 may (i) control the wireless network status icon 116 to have a third color to indicate that the wireless network is enabled, (ii) control the wireless network status icon 116 to have a fourth color to indicate that the wireless network is disabled, (iii) control the wireless network status icon 116 to have a fifth color to indicate that a security feature (e.g., WPS) of the wireless network is enabled, and/or (iv) control the wireless network status icon 116 to have a sixth color to indicate that the security feature of the wireless network is disabled. In some examples, the third color, the fourth color, the fifth color and/or the sixth color may be selected from a set of colors that the third set of light sources 322 are configured to emit (e.g., blue, green, orange, red, white and/or one or more other colors).

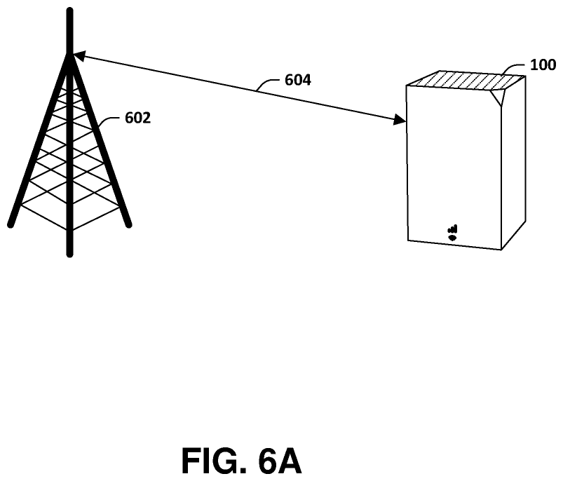

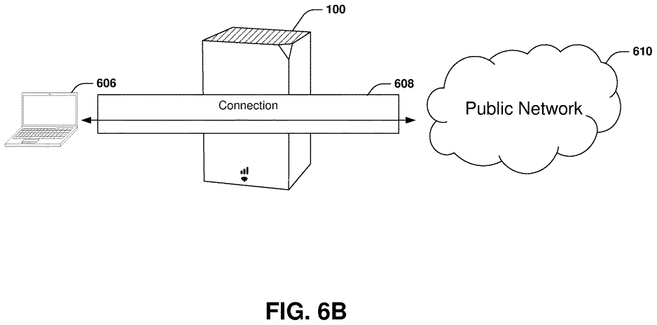

FIG. 6A illustrates the networking apparatus 100 communicating with a telecommunication service site 602, such as a wireless communication site. For example, signals 604 (e.g., uplink signals and/or downlink signals) may be transmitted between the telecommunication service site 602 and the networking apparatus 100. The networking apparatus 100 may be provided with a telecommunication service by the telecommunication service site 602, such as at least one of cellular service (e.g., 5G service, 4G service and/or other type of cellular service), internet service (e.g., cellular internet service, satellite internet service, 5G internet service, 4G internet service, and/or other type of internet service), etc. In an example, the telecommunication service site 602 may be (and/or may comprise) at least one of an antenna branch, a base station, an antenna tower, a transmission and/or reception point (TRP), etc.

In some examples, the networking apparatus 100 determines a signal strength based upon one or more measurements (e.g., signal quality measurements, power measurements, Reference Signal Received Power (RSRP), etc.) of one or more signals (e.g., downlink signals among the signals 604) received by the networking apparatus 100 from the telecommunication service site 602. The signal strength indicator icon 114 may be controlled based upon the signal strength. The networking apparatus 100 may monitor for changes to the signal strength, and/or may update the signal strength indicator icon 114 in response to detecting a change to the signal strength.

FIG. 6B illustrates the networking apparatus 100 establishing a connection 608 (e.g., an Internet connection) between a client device 606 (e.g., at least one of a phone, a laptop, a computer, a wearable device, a smart device, a television, any other type of computing device, hardware, etc.) and a public network 610 (e.g., the Internet), according to some embodiments. In some examples, the client device 606 is connected to the wireless network (e.g., WLAN, such as Wi-Fi network) established by the networking apparatus 100. For example, the connection 608 may comprise a connection (e.g., an encrypted wireless connection over the wireless network) between the client device 606 and the networking apparatus 100 and/or a connection (e.g., an encrypted connection over a WAN) between the networking apparatus 100 and the public network 610, which may be established using the telecommunication service provided by the telecommunication service site 602. The client device 606 may access resources (e.g., internet resources, such as websites, webpages, web applications, etc.) over the connection 608.

In some examples, the networking apparatus 100 may correspond to an Internet gateway. The networking apparatus 100 may comprise a client-side router (e.g., a home router, a broadband home router (BHR), a satellite office router, etc.). The client-side router may be positioned in a location (e.g., in at least one of a home, a home office, a satellite office, etc.) and/or may be used by one or more users (e.g., a household) at the location to access the Internet and/or one or more remote networks. Alternatively and/or additionally, the networking apparatus 100 may comprise a hotspot device. The hotspot device may provide devices (e.g., devices that are within range of the hotspot device) with network connections (e.g., Internet connections). The hotspot device may have internet service provided by the telecommunication service site 602 (e.g., the internet service may comprise at least one of cellular internet service, 5G internet service, 4G internet service, satellite internet service, and/or other type of internet service). The hotspot device may share the internet service with the client device 606 (over the WLAN, for example).

In accordance with some embodiments, a networking apparatus is provided. The networking apparatus includes a set of networking components, a housing assembly configured to house the set of networking components, a set of light sources, and a light guide disposed between the set of light sources and a first housing panel of the housing assembly. The first housing panel includes a first portion having a first thickness and a second portion adjacent the first portion and having a second thickness less than the first thickness. The light guide is configured to direct light from the set of light sources to an inner side of the second portion of the first housing panel to produce a networking icon on an outer side of the second portion of the first housing panel.

In accordance with some embodiments, a networking apparatus is provided. The networking apparatus includes a set of networking components and a housing assembly configured to house the set of networking components. The housing assembly comprises a venting structure overlying the set of networking components. The venting structure comprises a set of z-shaped louvers comprising a first z-shaped louver and a second z-shaped louver.

In accordance with some embodiments, a jig for disassembling a networking apparatus is provided. The jig includes a jig body and a first protrusion protruding from the jig body and configured to contact a first coupling feature of the networking apparatus when the networking apparatus is set in a first position relative to the jig body. When the first coupling feature is in an engaged state, the first coupling feature couples a housing panel of the networking apparatus to a housing body of the networking apparatus. The contact of the first protrusion with the first coupling feature disengages the first coupling feature to allow the housing body to be moved relative to the housing panel.

Unless specified otherwise, “first,” “second,” and/or the like are not intended to imply a temporal aspect, a spatial aspect, an ordering, etc. Rather, such terms are merely used as identifiers, names, etc. for features, elements, items, etc. For example, a first object and a second object generally correspond to object A and object B or two different or two identical objects or the same object.

Moreover, “example” is used herein to mean serving as an example, instance, illustration, etc., and not necessarily as advantageous. As used herein, “or” is intended to mean an inclusive “or” rather than an exclusive “or”. In addition, “a” and “an” as used in this application are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, and/or variants thereof are used in either the detailed description or the claims, such terms are intended to be inclusive in a manner similar to the term “comprising”.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing at least some of the claims.

Also, although the disclosure has been shown and described with respect to one or more implementations, alterations and modifications may be made thereto and additional embodiments may be implemented based upon a reading and understanding of this specification and the annexed drawings. The disclosure includes all such modifications, alterations and additional embodiments and is limited only by the scope of the following claims. The specification and drawings are accordingly to be regarded in an illustrative rather than restrictive sense. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A networking apparatus, comprising:
a set of networking components;
a housing assembly configured to house the set of networking components, wherein the housing assembly comprises a first housing panel comprising:
a first portion having a first thickness; and
a second portion adjacent the first portion and having a second thickness less than the first thickness;
a set of light sources; and
a light guide disposed between the set of light sources and the first housing panel and configured to direct light from the set of light sources to an inner surface of the second portion of the first housing panel to produce a networking icon on an outer surface of the second portion of the first housing panel.

2. The networking apparatus of claim 1, wherein:
the set of light sources comprises a first light source;
the networking apparatus comprises a controller connected to the first light source and configured to control a color of light emitted by the first light source into the light guide to control a color of the networking icon; and
the color of the networking icon is representative of a status of the networking apparatus.

3. The networking apparatus of claim 2, wherein:
the networking apparatus is configured to establish a wireless network with a client device; and
the controller is configured to at least two of:
control the networking icon to have a first color to indicate that the wireless network is enabled;
control the networking icon to have a second color to indicate that the wireless network is disabled;
control the networking icon to have a third color to indicate that a security feature of the wireless network is enabled; or
control the networking icon to have a fourth color to indicate that the security feature of the wireless network is disabled.

4. The networking apparatus of claim 1, wherein:
the networking apparatus is configured to monitor a signal strength of a telecommunication service provided by a telecommunication service site;
the networking icon corresponds to a signal strength indicator comprising a plurality of bars comprising a first bar and a second bar;
the networking apparatus comprises a controller connected to the set of light sources; and
the controller is configured to at least two of:
activate the first bar and activate the second bar to indicate that the signal strength is within a first range of signal strengths;
activate the first bar and deactivate the second bar to indicate that the signal strength is within a second range of signal strengths; or
deactivate the first bar and deactivate the second bar to indicate that the signal strength is within a third range of signal strengths.

5. The networking apparatus of claim 3, wherein:
the networking apparatus is configured to:
monitor a signal strength of a telecommunication service provided by a telecommunication service site; and
establish a connection between the client device and the Internet via the telecommunication service and the wireless network;
the networking apparatus comprises a second set of light sources;
the light guide is disposed between the second set of light sources and the first housing panel and configured to direct light from the second set of light sources to an inner surface of a third portion of the first housing panel to produce a second networking icon on an outer surface of the third portion of the first housing panel;
the second networking icon corresponds to a signal strength indicator comprising a plurality of bars comprising a first bar and a second bar; and
the controller is configured to at least two of:
activate the second bar and activate the third bar to indicate that the signal strength is within a first range of signal strengths;
activate the second bar and deactivate the third bar to indicate that the signal strength is within a second range of signal strengths; or
deactivate the second bar and deactivate the third bar to indicate that the signal strength is within a third range of signal strengths.

6. The networking apparatus of claim 1, wherein:
the light guide comprises a double injection light guide.

7. The networking apparatus of claim 1, wherein:
the light guide comprises polycarbonate.

8. The networking apparatus of claim 1, wherein the housing assembly comprises:
a venting structure overlying the set of networking components and comprising a set of z-shaped louvers comprising:
a first z-shaped louver; and
a second z-shaped louver.

9. The networking apparatus of claim 8, wherein:
the housing assembly defines a housing chamber in which the set of networking components are disposed;
the set of z-shaped louvers obstructs visibility into the housing chamber from a first perspective; and
the set of z-shaped louvers allows visibility into the housing chamber from a second perspective.

10. A networking apparatus disassembly system comprising:
the networking apparatus of claim 1, comprising a first coupling feature that, when in an engaged state, couples a base of the housing assembly to a housing body of the housing assembly; and
a jig for disassembling the networking apparatus, the jig comprising:
a jig body; and
a first protrusion protruding from the jig body and configured to contact the first coupling feature when the networking apparatus is set in a first position relative to the jig body, wherein the contact of the first protrusion with the first coupling feature disengages the first coupling feature to allow the housing body to be moved relative to the base.

11. The networking apparatus disassembly system of claim 10, wherein:
the housing assembly comprises a chassis configured to support one or more components of the set of networking components; and
the movement of the housing body relative to the base exposes at least some of the chassis and at least some of the set of networking components.

12. The networking apparatus disassembly system of claim 10, wherein:
the first protrusion extends through an opening defined by the base to contact the first coupling feature.

13. The networking apparatus disassembly system of claim 12, wherein:
the base comprises a venting structure comprising a first louver and a second louver; and
the opening is defined by the first louver and the second louver.

14. The networking apparatus disassembly system of claim 10, wherein:
the housing body comprises the first housing panel;
the jig comprises a first spacing tool protruding from the jig body and configured to at least one of:
separate the first housing panel from an indicator light assembly comprising the light guide and the set of light sources by a first distance; or
mitigate a force from the first housing panel to the indicator light assembly during the movement of the housing body relative to the base.

15. A networking apparatus, comprising:
a set of networking components; and
a housing assembly configured to house the set of networking components, wherein the housing assembly comprises a venting structure overlying the set of networking components and comprising a set of z-shaped louvers comprising a first z-shaped louver and a second z-shaped louver.

16. The networking apparatus of claim 15, wherein:
the housing assembly defines a housing chamber in which the set of networking components are disposed;
the set of z-shaped louvers obstructs visibility into the housing chamber from a first perspective; and
the set of z-shaped louvers allows visibility into the housing chamber from a second perspective.

17. A jig for disassembling a networking apparatus, the jig comprising:
a jig body; and
a first protrusion protruding from the jig body and configured to contact a first coupling feature of the networking apparatus when the networking apparatus is set in a first position relative to the jig body, wherein:
when the first coupling feature is in an engaged state, the first coupling feature couples a housing panel of the networking apparatus to a housing body of the networking apparatus; and
the contact of the first protrusion with the first coupling feature disengages the first coupling feature to allow the housing body to be moved relative to the housing panel.

18. The jig of claim 17, wherein:
the movement of the housing body relative to the housing panel exposes at least some of a set of networking components of the networking apparatus.

19. The jig of claim 17, wherein:
the first protrusion extends through an opening defined by the housing panel to contact the first coupling feature.

20. The jig of claim 19, wherein:
the networking apparatus comprises a venting structure comprising a first louver and a second louver; and
the opening is defined by the first louver and the second louver.
